(19) United States
(12) Patent Application Publication
(10) Pub. No.: US 2019/0198405 A1
(43) Pub. Date: Jun. 27, 2019

(54) STATISTICAL FRAMEWORK FOR TOOL CHAMBER MATCHING IN SEMICONDUCTOR MANUFACTURING PROCESSES

(71) Applicant: International Business Machines Corporation, Armonk, NY (US)

(72) Inventors: Zhiguo LI, Yorktown Heights, NY (US); Robert J. BASEMAN, Brewster, NY (US)

(21) Appl. No.: 15/853,425

(22) Filed: Dec. 22, 2017

(51) Int. Cl. H01L 21/66; G05B 15/02; G05B 19/042; G05B 19/18

(52) U.S. Cl. CPC H01L 22/30; G05B 15/02; G05B 2219/50; G05B 19/182; G05B 19/0425

(57) ABSTRACT

Detecting mismatches among a plurality of manufacturing tools of the same type and operating on a first semiconductor wafer. A server receives metrological data and time series data applicable to the first semiconductor wafer from each of the plurality of manufacturing tools. The server applies a plurality of statistical tests to the metrological data and a data mining technique to the time series data. The server assigns a score to each result from applying the plurality of statistical test and the data mining technique to the plurality of manufacturing tools, the scores indicating a degree of mismatch among the plurality of manufacturing tools. Responsive to the sum of scores exceeding a predetermined threshold, the server declares a mismatch condition for each tool among the plurality of manufacturing tools.

### BACKGROUND

The present invention relates to semiconductor device manufacturing, and more specifically, to a method and apparatus for detecting and reporting mismatches among a plurality of manufacturing tools of the same type.

In semiconductor device fabrication, a set of processing steps is performed on a wafer, individual die on the wafer, and/or on discrete die using a variety of manufacturing tools, including photolithography steppers, etch tools, deposition tools, polishing tools, rapid thermal process tools, implantation tools, test equipment tools, etc. One technique for improving the operation of a semiconductor processing line includes using a factory wide control system to automatically control the operation of the various manufacturing tools. The manufacturing tools communicate with a manufacturing framework or a network of processing modules. Each manufacturing tool is connected to an equipment interface. The equipment interface is connected to a machine interface which facilitates communications between the manufacturing tool and the manufacturing framework. The machine interface can be part of an advanced process control (APC) system. The APC system initiates a control script based upon a manufacturing model, which can be a software program that automatically retrieves the data needed to execute a manufacturing process. Often, semiconductor devices are staged through multiple manufacturing tools for multiple processes, generating data relating to the quality of the processed semiconductor devices. Pre-processing and/or post-processing data is supplied to process controllers for the manufacturing tools. Operating recipe parameters are calculated by the process controllers based on the performance model and the pre-processing and/or post-processing data to attempt to achieve post-processing results as close to a target value as possible. Reducing variation in this manner leads to increased throughput, reduced cost, higher device performance, etc.

At a given process step, one or more manufacturing tools of the same type may be available for performing the required processing. Although the various manufacturing tools are capable of performing the same process on the lot, the tools may not operate at the same level of proficiency (i.e., tool health). For example, one tool may be near the end of an interval between cleaning cycles. In some instances, when a tool is nearer the end of its cleaning interval, the wafers processed in the tool may exhibit a higher particle contamination rate, as compared to a tool nearer the front end of its cleaning interval. A higher particle contamination rate can degrade the grade or yield of the wafers processed in the tool.

Given the disparities across the process tools for a given step, it is useful to keep the equipment matched (including all chambers, and sub-chambers) to ensure consistent yields. The term “chamber matching” has many definitions. One definition is that two chambers that produce the same output are matched. That is, the outputs of the chambers are matched without regard to matching the inputs of the chambers. The chambers may be producing the same data values in very different ways. For example, a first furnace uses high-temp and low-time while a second furnace uses low-temp and high-time to produce the same output (e.g., both produce the same film thickness), but with very different inputs. Unfortunately, it is often difficult to identify a mismatch of the manufacturing tools and proper analyses may take weeks to complete.

Therefore, there is a need in the art for improved techniques of detecting mismatches among multiple processing tools of the same type.

### SUMMARY

According to one embodiment of the present disclosure, a server receives metrological data and time series data applicable to the first semiconductor wafer from each of the plurality of manufacturing tools. The server applies a plurality of statistical tests to the metrological data and a data mining technique to the time series data. The server assigns a score to each result from applying the plurality of statistical test and the data mining technique to the plurality of manufacturing tools, the scores indicating a degree of mismatch among the plurality of manufacturing tools. Responsive to the sum of scores exceeding a predetermined threshold, the server declares a mismatch condition for each tool among the plurality of manufacturing tools.

### BRIEF DESCRIPTION OF THE SEVERAL VIEWS OF THE DRAWINGS

FIG. 1 depicts a manufacturing system in which embodiments of the present disclosure may be implemented.

FIG. 2 illustrates components of a statistical analysis engine of FIG. 1 according to embodiments of the present disclosure.

FIG. 3 illustrates a functional diagram of the procedure, relevant inputs, and relevant outputs of the statistical analysis engine according to embodiments of the present disclosure.

FIG. 4 illustrates one embodiment of a method for detecting incompatibilities among a plurality of manufacturing tools operating on a semiconductor wafer, according to some embodiments of the present disclosure.

FIG. 5 illustrates an example computing system used to detect incompatibilities among a plurality of manufacturing tools operating on a semiconductor wafer, according to some embodiments of the present disclosure.

### DETAILED DESCRIPTION

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

In the following, reference is made to embodiments presented in this disclosure. However, the scope of the present disclosure is not limited to specific described embodiments. Instead, any combination of the following features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.Aspects of the present disclosure provide an improved method and system for detecting chamber mismatches in a plurality of chambers of the same type. The system provides an integrated statistical framework based on on-wafer measurements instead of trace data (signal data) by using multiple statistical techniques, data mining methods, and data visualization tools. The system detects mismatches using sliding time windows. As used herein, sliding time windows refer to the collection of on-wafer measurement data of the wafers collected over time. For example, chamber matching is tested and scores are calculated, for example, every week using the past four-week data. In this sense, a sliding 4-week time window is used in the system.

The system employs multiple analytical methods to confirm importance. The system employs wafer specifications to assure that mismatches are operationally, not just statistically, significant. The system analyses different populations of wafers to confirm mismatches among one or more tools of the same type (mismatches are observed for multiple technologies, or family codes, or measurement equipment). The system analyses paired tool sets—e.g., hard mask open tools coupled with subsequent etch (e.g., DTHMO & HMO). The analysis results in the identification of significant differences in on-wafer measurements, for instance on the basis of, but not limited to, processing chambers used, measurement tools used, technology, and product. The system is configured to generate multi-level alerts for bad-behaved and/or mismatched tools. The system employs an integrated visualization interface and alert reporting system.

The system automatically conducts a plurality of statistically and operationally relevant analyses, and automatically detects whether the results of the analyses are internally consistent in identifying a chamber mismatch of operational importance. Thus reducing time to detect operationally significant mismatches from as much as weeks to as little as minutes post wafer processing measurements. The detection accuracy is improved.

In an example, the system computes from several statistical, data mining, and visualization analyses an overall score derived from a weighted sum of a plurality of scores generated by a statistical analysis engine. The system compares the overall score to a threshold value decided by the experts. If the overall score exceeds the threshold, the system issues a tool inhibition signal to disable the affected mismatched tools in the system.

A comprehensive user interface showing scores (individual and overall) with colors marking severity levels (green, yellow and red) in order to deliver important information to users in a straightforward and easy to understand manner. With the scores and illustration of figures (scatter plots and box plots), engineers may quickly identify the mismatched chambers.

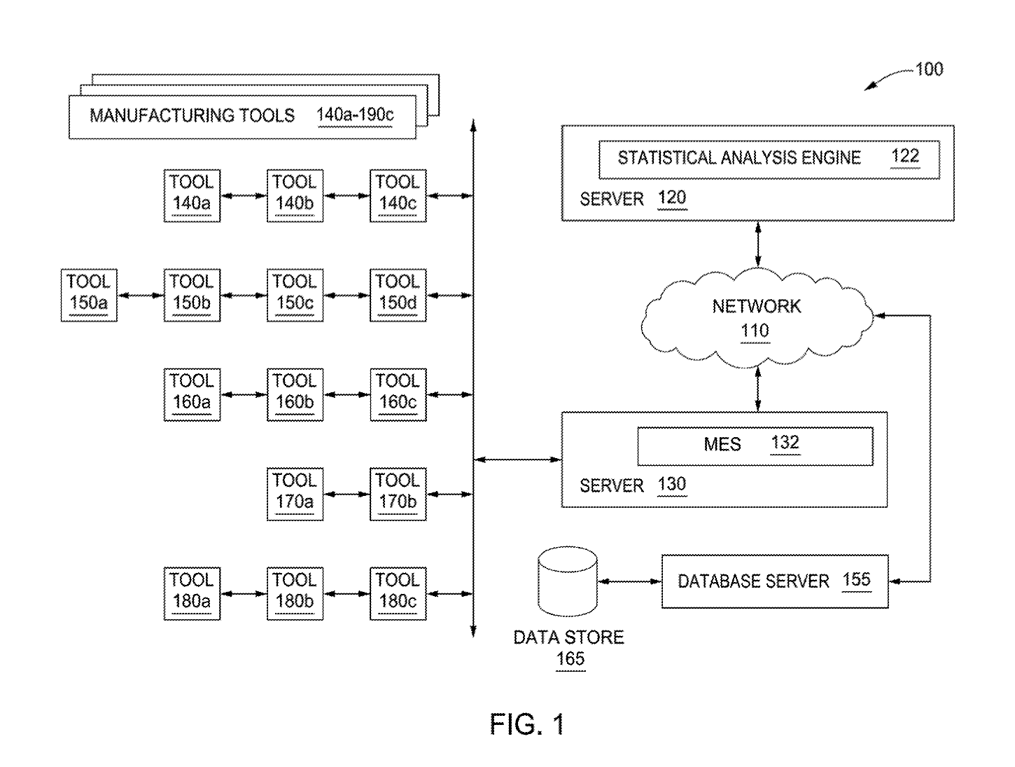

FIG. 1 depicts a manufacturing system 100 in which embodiments of the present disclosure may be implemented. As shown, manufacturing system 100 includes a server 120 which is connected via network 110 to another server 130 which is connected to a plurality of manufacturing tools 140a-190c. Network 110 may, for example, comprise the Internet. In another embodiment, the manufacturing tools 140a-190c are also connected directly to server 120.

Server 120 may comprise a computing device such as a rack server, desktop or laptop computer, mobile phone, tablet, or other suitable computing device. As shown, the server 120 comprises a statistical analysis engine 122 which may perform operations described herein related to determining and predicting mismatches of tools of the same type when the manufacturing tools 140a-190c perform a plurality of processing steps on a wafer. For example, statistical analysis engine 122 may analyze information received from a manufacturing execution system (MES) 132 of server 130 (e.g., chip design data, defect data, information about the manufacturing process, information about the manufacturing tools, and metrology data) in order to identify mismatches of manufacturing tools. In some embodiments, the server 120 is separate from the manufacturing tools 140a-190c. In other embodiments, the server 120 may be part of the manufacturing tools 140a-190c or may be an off-line server.

Server 130 may comprise a computing device such as a rack server, desktop or laptop computer, mobile phone, tablet, or other suitable computing device. As shown, server 130 comprises the MES 132, which may perform operations described herein related to detecting mismatches among manufacturing tools. For example, MES 132 may coordinate processes performed by the plurality of manufacturing tools 140a-190c, and may collect data from these tools (e.g., alignment data, chip design data, defect data, information about the manufacturing process, information about the parameters of the manufacturing tools 140a-190c, and metrology data). MES 132 may provide this information to statistical analysis engine 122 (e.g., over network 110), which may analyze the information and provide predictive information to statistical analysis engine 122 in return. In some embodiments statistical analysis engine 122 may provide instructions to MES 132 regarding corrective action to take with respect to a mismatched manufacturing tool (e.g., 140a), or other aspects of the manufacturing process. In certain embodiments, MES 132 automatically takes corrective action, such as by instructing individual manufacturing tools 140a-190c to perform certain tasks (e.g., instructing a lithography tool to strip and recoat a substrate in order to correct an alignment defect or instructing a deposition tool to alter one or more parameters).

Manufacturing tools 140a-190c may comprise one or more tools which perform processes related to manufacturing silicon substrates. For example, manufacturing tools 140a-190c may include lithography tools (e.g., including mechanical and optical alignment tools), etching tools, deposition tools, and planarization tools. Manufacturing tools 140a-190c may communicate with MES 132 in order to receive instructions and provide information about, for example, substrates, defects, parameters, and the manufacturing process.

The manufacturing system 100 is adapted to fabricate semiconductor devices. Although the subject matter is described as it may be implemented in a semiconductor fabrication facility, the application of the techniques described herein is not so limited and may be applied to other manufacturing environments. The techniques described herein may be applied to a variety of manufactured items including, but not limited to microprocessors, memory devices, digital signal processors, application specific integrated circuits (ASICs), or other similar devices. The techniques may also be applied to manufactured items other than semiconductor devices.

Each of the manufacturing tools 140a-190c are grouped into sets of tools of the same type, as denoted by lettered suffixes. For example, the set of manufacturing tools 140a-190c represent tools of a certain type, such as a photolithography stepper that are capable of performing the same process operation. In the case of manufacturing tools 140a-190c with multiple chambers, the lettered suffixes may represent multiple chambers of a single process tool. A particular wafer or lot of wafers progresses through the manufacturing tools 140a-190c as it is being manufactured, with each of the manufacturing tools 140a-190c performing a specific function in the process flow. Exemplary manufacturing tools for a semiconductor device fabrication environment, include metrology tools, photolithography steppers, etch tools, deposition tools, polishing tools, rapid thermal process tools, implantation tools, test equipment tools, etc. The manufacturing tools 140a-190c are illustrated in a rank and file grouping for illustrative purposes only. In an actual implementation, the manufacturing tools 140a-190c may be arranged in any order of grouping. Additionally, the connections between the tools in a particular grouping are meant to represent only connections to the network 110, rather than interconnections between the tools.

Although the manufacturing system 100 is described as it may be implemented for scheduling lots of manufactured items, it may also be used schedule individual manufactured items. The MES 132 of server 130 directs the high level operation of the manufacturing system 100. The MES 132 monitors the status of the various entities in the manufacturing system 100 (i.e., lots, the manufacturing tools 140a-190c and controls the flow of articles of manufacture (e.g., lots of semiconductor wafers) through the process flow. The MES 132 may also be referred to as a scheduling server. A database server 155 is provided for storing data related to the status of the various entities and articles of manufacture in the process flow. The database server 155 may store information in a data store 165. The data may include pre-process and post-process metrology data, tool trace data, lot priorities, etc. The manufacturing system 100 also includes the statistical analysis engine 122. As described in greater detail below, the statistical analysis engine 122 monitors metrology data from the manufacturing tools 140a-190c to identify mismatches between grouped manufacturing tools 140a-190c. As used herein metrology data refers to data derived from on-wafer measurements but not from wafers on the production line. Ex situ equipment is used to take measurements away from the processing equipment, often in a centralized location. Although ex situ process control area is very broad, characteristics and trends can be grouped into measuring the two-dimensional components of a wafer (often called critical dimension [CD] measurements) and measuring the three-dimensional components of the wafer (often referred to in this context as a “thin film”). Characteristics such as thickness, chemical composition, and structure are needed for the operation of a semiconductor device as designed.

The distribution of the processing and data storage functions amongst the different servers in FIG. 1 is generally conducted to provide independence and central information storage. Of course, different numbers of servers and different arrangements may be used.

Statistical analysis engine 122 may also make determinations about particular mismatched manufacturing tools 140a-190c based on information received from MES 132. For example, statistical analysis engine 122 may determine whether a particular mismatched tool (e.g., 140a) requires corrective action to be taken. Statistical analysis engine 122 may analyze a potential mismatch in view of the information it has received (e.g., alignment data, chip design data, defect data, information about the manufacturing process, information about the manufacturing tools, and metrology data) in order to determine whether a mismatch is substantial enough to cause a problem, and then return instructions to MES 132 regarding whether or not to take corrective action.

In another example, statistical analysis engine 122 may employ multiple statistical techniques, data mining methods, and data visualization tools to analyze metrology data of wafers processed in multiple chambers of the same type to proactively detect chamber mismatches. The statistical analysis engine 122 may dynamically detect both statistically and operationally significant mismatch signals using manufacturing tool product specification limits and confirm mismatches using multiple analytical methods performed on a plurality of wafer populations. The statistical analysis engine 122 may generate and report multi-level alerts and statistically derived mismatch scores for bad behaved and/or mismatched manufacturing tools using to an integrated visual interface and alert reporting system. The statistical analysis engine 122 may employ statistical model based methods (e.g., hypothesis testing) and data mining based methods (e.g., dynamic time warping) to proactively detect chamber mismatches. The statistical analysis engine 122 may employ statistical testing with specification limits to detect operationally significant signals. The statistical analysis engine 122 may confirm mismatches using multiple statistical methods and/or data mining methods from different wafer populations. The statistical analysis engine 122 may compute an overall mismatch score that is compared to a pre-defined threshold, and if the threshold is exceeded, the statistical analysis engine 122 generates multi-level alerts and may trigger a tool inhibition signal applicable to the identified mismatched tool. The generated alerts may be illustrated and reported through an integrated display interface and reporting system. The generated alerts may be presented to engineers for review and the manufacturing system 100 may take corrective engineering actions to resolve detected mismatches. Detection of mismatches may consider combinations of chambers used in multiple manufacturing operations.

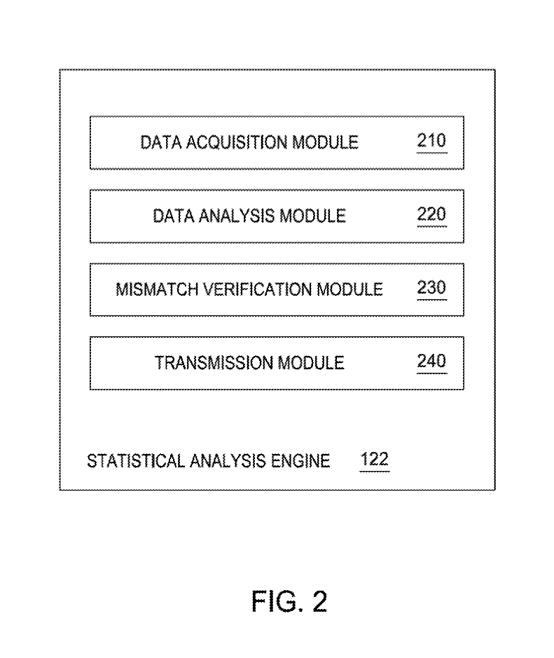

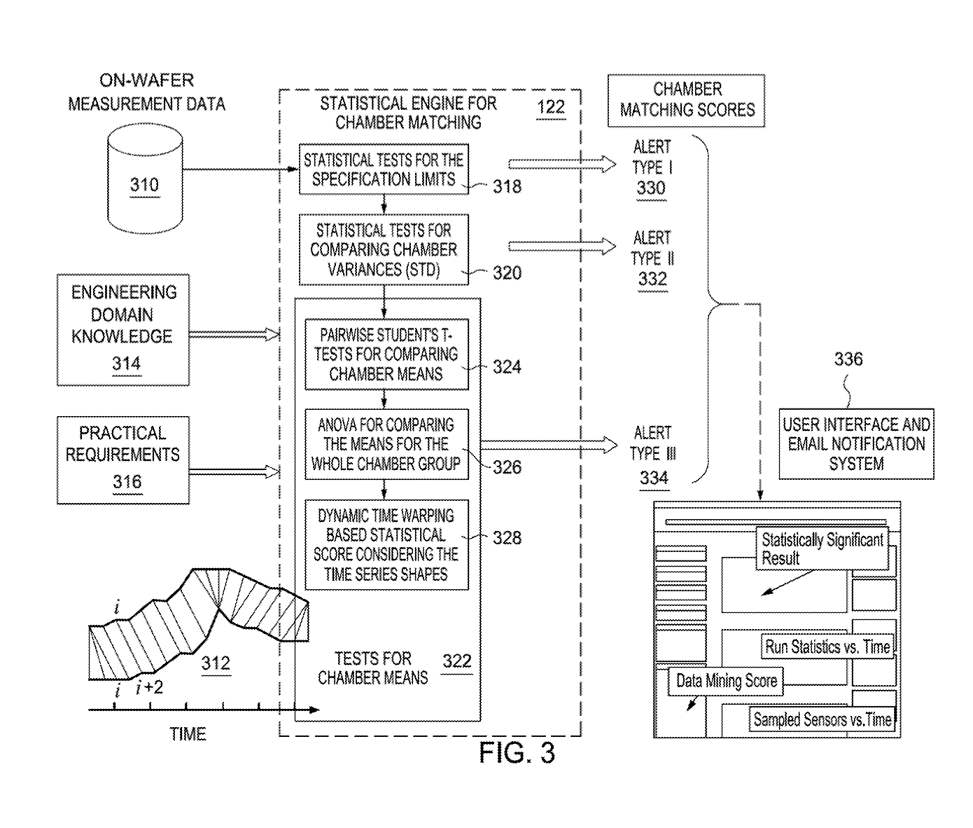

FIG. 2 illustrates components of the statistical analysis engine 122 according to embodiments of the present disclosure. As shown, the statistical analysis engine 122 includes a data acquisition module 210, which may acquire metrological data from MES 132 (e.g., over network 110). Statistical analysis engine 122 further includes a data analysis module 220, which may statistically analyze data received from MES 132 in order to identify potential mismatched manufacturing tools 140a-190c. Statistical analysis engine 122 further includes a mismatch verification module 230, which may confirm the presence of one or more mismatched tools based on determinations made by data analysis module 220. Data analysis module 220 and mismatch verification module 230 may, for example, make determinations based on fundamental statistical processes and data mining analyses of metrological data received from MES 132. As used herein, the data mining analyses employed include: outlier detection (z-score, linear regression models, information theory models), and time series clustering (e.g., hierarchical clustering, partitional clustering) based on the dynamic time warping distance (DTW). Statistical analysis engine 122 further includes a transmission module 240, which may transmit alarm data and corrective instructions to MES 132 (e.g., over network 110). FIG. 3 illustrates a functional diagram of the procedure, relevant inputs, and relevant outputs of the statistical analysis engine 122 according to embodiments of the present disclosure. The statistical analysis engine 122 may receive metrological data 310 (on-wafer measurements) over the network 110 from the MES 132 and originating from the data store 165 serviced by the database server 155. The statistical analysis engine 122 may further receive time series data 312, engineering domain knowledge data 314, and practical requirements 316. As an example, the process engineers may provide the specification limits of the wafer measurements. In the module 318, the engineers can also specify the value of N in LSL+N*sigma and USL−N*sigma. For example, N=3, 4, or 5.

Engineering domain knowledge 314 refers to background knowledge provided by engineers about the chambers and a list of Key Performance Indicators (KPIs). The engineers may review the identified statistically significant mismatching signals and determine if they are also operationally significant. The engineers can also provide information about the changes in the chambers and explain the reasons behind the significant signals.

The statistical analysis engine 122 performs statistical tests for specification limits 318 on the chambers and wafer being processed. Chambers may be matched in terms of variance and means of measurement signals (variables). Tests of specification limits 318 on the chambers and wafer may include, for example, hypothesis testing on means of normal distribution with unknown variance (μ<μ₀ or μ>μ₀). The statistical analysis engine 122 performs statistical tests on the metrological data 310 for comparing chamber variances 320. This includes, for example, hypothesis testing on variances of normal distributions (δ₁²=δ₂²).

The statistical analysis engine 122 further performs a plurality of tests for chamber means 322, involving pairwise student's t-tests for comparing chamber means 324 (:hypothesis testing on means of normal distribution with unknown (μ₁=μ₂)., Analysis of Variance tests 326, including the F-test for comparing the means of multiple chamber groups, and dynamic time warping (DTW) 328 based statistical scoring on the time series data 312 that considers time series shapes. In order to calculate the data mining score using the dynamic time warping distance, three steps need to be completed: (1) detect and remove outliers using the anomaly detection methods (z-score, linear regression models, information theory models)—for the measurement data, the outliers in each chamber should be removed. After the outliers are removed, (2) perform time series clustering in order to find the matched chambers. First, the dynamic time warping (DTW) distance between two time series (measurement variable s from two chambers, s₁(t) and s₂(t)) is calculated. Second, the clustering is implemented using hierarchical clustering or partitional clustering based on the dynamic time warping distance (DTW). (3) The DTW distance values may be compared to the reference distribution of the DTW distance of s calculated for the matched chambers using the historical data. If the distance is greater the 95^{th} percentile or smaller than the 5^{th} percentile, it may be stated that that the two chambers are mismatched for the measurement variables. The DTW score may also take the shape of the measurement signal into consideration. First, the Dynamic Time Warping (DTW) distance between two time series (measurement variable s from two chambers, s₁(t) and s₂(t)) is calculated. This value may be compared to the reference distribution of the DTW distance of s calculated for the matched chambers using the historical data. If the distance is greater the 95^{th} percentile or smaller than the 5^{th} percentile, then it may be stated that the two chambers are mismatched for the measurement variables. From these analyses, the statistical analysis engine 122 assigns an overall chamber matching score 320.

If the overall chamber matching score 320 exceeds a predefined threshold, then the statistical analysis engine 122 generates different levels of alarms 330, 332, 334 based on the scores from the tests performed and the statistical analysis engine 122 further issues a tool inhibit signal to disable the mismatched tool(s). The scores and alarms are displayed using a user interface and email notification system 336. The kinds of scores and alarms displayed in the user interface and email notification system, may be, for example, time series plots of the measurement data over time; box plots of the measurement data by chamber; p-values of statistical tests for chamber variations and means (see references 318, 320, 324 and 326 of FIG. 3), as well as a data mining score using the time warping distance (see reference 328 of FIG. 3).

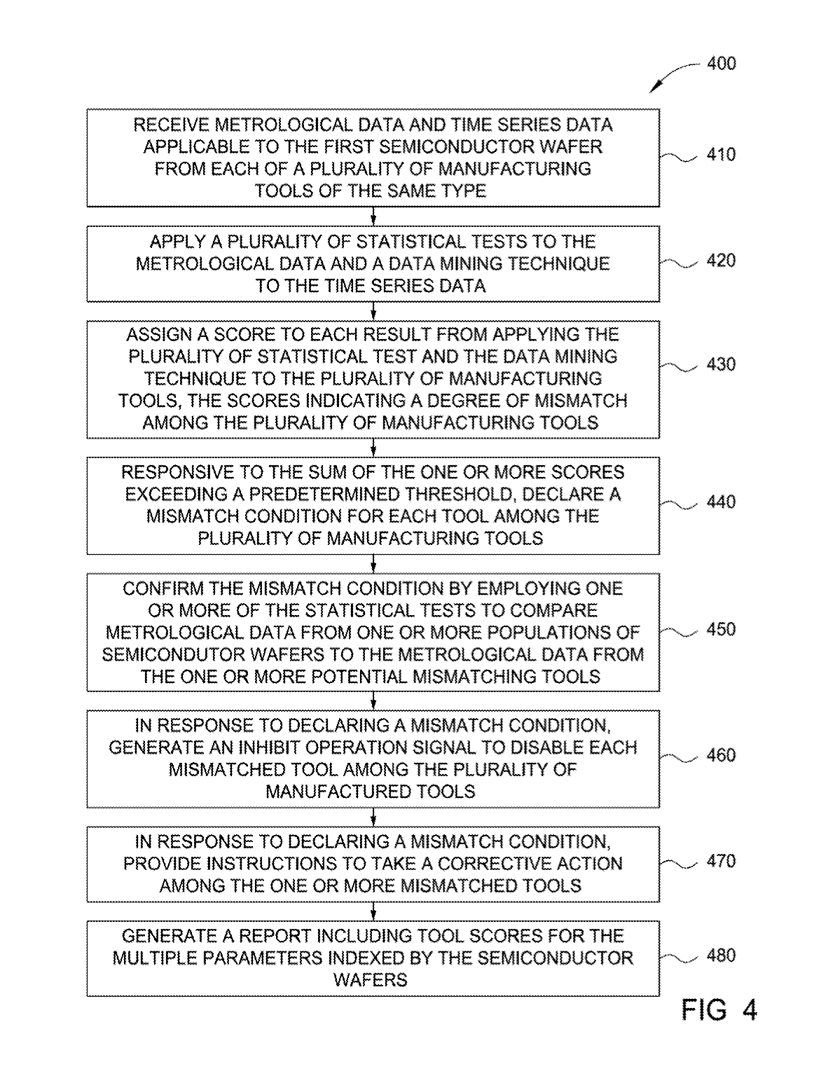

FIG. 4 illustrate one embodiment of a method 400 for detecting mismatches among a plurality of manufacturing tools of the same type and operating on a semiconductor wafer. Method 400 can be performed by processing logic that can comprise hardware (e.g., circuitry, dedicated logic, programmable logic, microcode, etc.), software (e.g., instructions run on a processing device), or a combination thereof. In one embodiment, method 600 is performed by the statistical analysis engine 122 of FIG. 1.

At block 410, the statistical analysis engine 122 receives metrological data and time series data applicable to the first semiconductor wafer from each of the plurality of manufacturing tools. At block 420, the statistical analysis engine 122 applies a plurality of statistical tests to the metrological data and a data mining technique to the time series data. In an example, the plurality of the statistical tests determines whether the metrological series data exceeds wafer specification limits. In an example, the plurality of the statistical tests compares variances among chamber measurements in the metrological data. The plurality of the statistical tests may be one or more tests for types of means in the metrological data. The plurality of the statistical tests may be one or more t-tests for comparing chamber means. The plurality of the statistical tests may be one or more comparisons of means for a full set of chambers comprising the set of manufacturing tools of similar types.

Chambers should be matched in terms of both variance and mean of the measurement signals (variables). This includes hypothesis testing on means of normal distribution with unknown variance (μ<μ₀ or μ>μ₀); hypothesis testing on variances of normal distributions (δ₁²=δ₂²); hypothesis testing on means of normal distribution with unknown (μ₁=μ₂); the analysis of variance F-test.

The module 318 can check if a chamber is working within the product specifications. The module 318 checks correct operation of a one single chamber by comparing the chamber with the specification limits and, if the test statistic (score) is in the rejection zone, the module 318 raises ran alarm that wafers produced in this chamber may not meet the specifications. Each other tests from the modules 320, 324, 328 compares a pair of related chambers (two related chambers) and, if the score is in the rejection zone, the module 320, 324, 328 raise an alarm that these two chambers are mismatched. The other tests from the modules 320, 324, 328 can identify the statistically significant mismatch signals (say at a significance level of 0.05). Domain experts can review the identified signals to determine if they are false alarms or not to confirm their operational significance. The test in module 318 may be a first text in a sequence of tests first test to make sure each single chamber meets the specifications before it is determined that there are mismatched chambers. This is to avoid the situation where there are two matched chambers but both of them do not meet the specifications.

The data mining technique may be a dynamic time warping technique. The dynamic time warping technique outputs results comprising a statistical score that is based on a time series shape of the time series data. The score of DTW also takes the shape of the measurement signal into consideration. First, the dynamic time warping (DTW) distance between two time series (measurement variable s from two chambers, s₁(t) and s₂(t)) is calculated. This value will be compared to the reference distribution of the DTW distance of s calculated for the matched chambers using the historical data. If the distance is greater the 95^{th} percentile or smaller than the 5^{th} percentile, we can say that the two chambers are mismatched for the measurement variable s.

At block 430, the statistical analysis engine 122 assigns a score to each result from applying the plurality of statistical test and the data mining technique to the plurality of manufacturing tools, the scores indicating a degree of mismatch among the plurality of manufacturing tools. Responsive to the sum of scores exceeding a predetermined threshold, the server declares a mismatch condition for each tool among the plurality of manufacturing tools. At block 440, responsive to the sum of the one or more scores exceeding a predetermined threshold, the statistical analysis engine 122 declares a mismatch condition for each tool among the plurality of manufacturing tools.

Applying the plurality of statistical tests determines one or more mismatches that are operationally significant based on wafer specifications.

At block 450, the statistical analysis engine 122 confirms the mismatch condition by employing one or more of the statistical tests to compare metrological data from one or more populations of semiconductor wafers to the metrological data from the one or more potential mismatching tools. The comparison of metrological data from a population of semiconductor wafers to the data from the one or more potential mismatching tools determines mismatches among multiple technologies, family codes, or measurement equipment. The comparison of metrological data from a population of semiconductor wafers to the data from the one or more potential mismatching tools compares analyses of paired tool sets.

At block 460, in response to declaring a mismatch condition, the statistical analysis engine 122 generates an inhibit operation signal to disable each mismatched tool among the plurality of manufacturing tools. At block 470, in response to declaring a mismatch condition, the statistical analysis engine 122 provides instructions to take a corrective action among the one or more mismatched tools. At block 480, the statistical analysis engine 122 generates a report including tool scores for the multiple parameters indexed by the semiconductor wafers, which may be indexed by the semiconductor wafers.

The statistical hypothesis tests generate values of test statistics (scores) and p-values. For the following tests, the test scores are:

(Module 318): hypothesis testing on means of normal distribution with unknown variance (H₀: μ=μ_{L} vs. H₁: μ<μ_{L}) for a single chamber: Here μ_{L}, is the specification mean calculated as LSL+N*sigma, where LSL is the lower specification limit and sigma is the standard deviation given by the specification. And the t-score

$${t}_{0} = \frac{\text{?}}{\text{?}}$$

$$\text{?} \text{indicates text missing or illegible when filed}$$

which follows the student's t distribution. The criteria for Rejection is t₀<−t_{α,n-1}, where α=0.05 is the significance level.

H₀: μ=μ_{J} vs. H₁: μ>μ_{U}—Here μ_{U} is the specification mean calculated as USL−N*sigma, where USL is the upper specification limit and sigma is the standard deviation given by the specification. The score is

$${t}_{0} = \frac{\text{?}}{\text{?}}$$

$$\text{?} \text{indicates text missing or illegible when filed}$$

which follows the t distribution, and the criteria for rejection is now t₀>t_{α, n-1}.

(Module 320): hypothesis testing on variances of normal distributions (H₀: δ₁²=δ₂² vs. H₁: δ₁²≠δ₂²) for a pair of chambers—F-score.

F=s₁²/s₂², which follows the F distribution. The criteria for rejection is F>F_{α/2, n1-1, n2-1} or F<F_{1-α/2, n1-1, n2-1}

(Module 324): hypothesis testing on means of normal distribution with unknown variance for a pair of chambers: (H₀: μ₁=μ₂ vs. H₁: μ₁≠μ₂): T-score

$$T = \frac{\overline{X} - \overline{Y}}{{S}_{{n}_{1} + {n}_{2} - 2} \sqrt{1 \text{/} {n}_{1} + 1 \text{/} {n}_{2}}} ∼ {t}_{{n}_{1} + {n}_{2} - 2} . \\ where {S}_{{n}_{1} + {n}_{2} - 2}^{2} = \frac{{n}_{1} - 1}{{n}_{1} + {n}_{2} - 2} {S}_{{n}_{1} - 1}^{2} + \frac{{n}_{2} - 1}{{n}_{1} + {n}_{2} - 2} {S}_{{n}_{2} - 1}^{2} , {s}_{n - 1}^{2} = \frac{1}{n - 1} {\sum }_{i = 1}^{n} {( {x}_{i} - \overline{x} )}^{2} .$$

This statistic follows the t-distribution and the rejection criteria is abs(T)>t_{α/2, n1+n2-2}, where abs(.) is the absolute value.

(Module 328): the score of DTW for a pair of chambers—The DTW score should be compared to the 95th percentile of the reference empirical distribution of the score generated from the matched chambers. If the score is greater than the threshold value—say, the 95th percentile (i.e., the DTW distance between two chambers is too large), then the two chambers are mismatched.

For each of the above tests, the p-value can be generated using the scores.

If there are multiple chambers, for every chamber, the t-score and the corresponding p-value can be calculated from module 318. Module 318 can determine if this chamber meets the specification limits or not. If the score meets the rejection criteria, then a single chamber does not meet the specification. For every pair of chambers, modules 320, 324, and 328 can calculate all the other three scores As long as one of the scores meet its rejection criteria, then the pair of the chambers are mismatched. Finally, modules 320, 324, and 328 can calculate the weighted average of the resulting p-value of the three tests (320, 324, 328) as the final metric. That is, the overall p_value=W₁*p_value from 320+W₂*p_value from 324+W₃*p_value from 328, and Wᵢ, i=1, 2, 3, is the weight and sum(Wᵢ)=1. The smaller the final p value, the more significant the mismatch signal. Using the overall p-value, the mismatched pairs of chambers can be ranked.

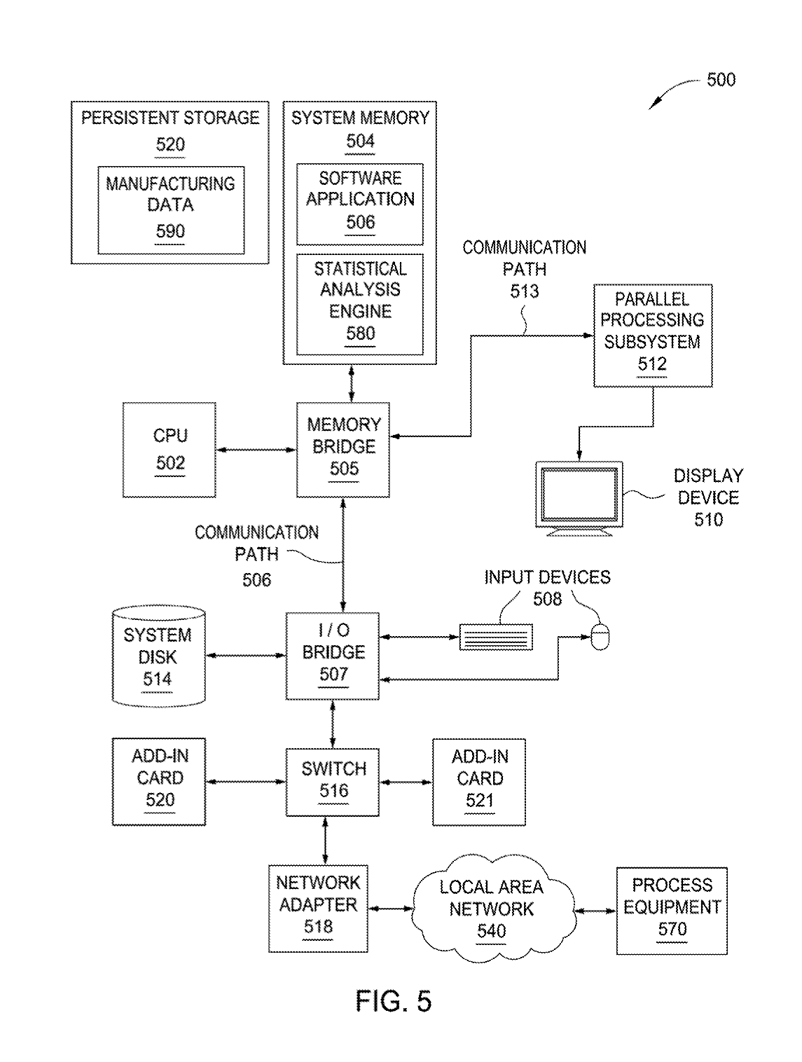

FIG. 5 illustrates an example computing system 500 used to detect incompatibilities among a plurality of manufacturing tools operating on a semiconductor wafer, according to some embodiments of the present disclosure. In certain embodiments, computer system 500 is representative of the server 120. Aspects of computer system 500 may also be representative of other devices used to perform techniques described herein (e.g., server 130). For example, computing system 500 may be a personal computer, industrial processor, personal digital assistant, mobile phone, mobile device or any other device suitable for practicing one or more embodiments of the present invention.

The system 500 includes a central processing unit (CPU) 502 and a system memory 504 communicating via a bus path that may include a memory bridge 505. CPU 502 includes one or more processing cores, and, in operation, CPU 502 is the master processor of the system 500, controlling and coordinating operations of other system components. System memory 504 stores a software application 506, and data, for use by CPU 502. CPU 502 runs software applications and optionally an operating system.

Illustratively, the system memory 504 includes the statistical analysis engine 580, which may correspond to the statistical analysis engine 122, which performs operations related to detecting sensor excursions, according to techniques described herein. For example, the statistical analysis engine 580 may be equivalent to the statistical analysis engine 122 in FIG. 1, and may use fundamental statistical processes and stochastic-based analyses of data captured during substrate manufacturing to detect and verify sensor excursions and other aspects of the manufacturing process.

Memory bridge 505, which may be, e.g., a Northbridge chip, is connected via a bus or other communication path (e.g., a HyperTransport link) to an I/O (input/output) bridge 507. I/O bridge 507, which may be, e.g., a Southbridge chip, receives user input from one or more user input devices 508 (e.g., keyboard, mouse, joystick, digitizer tablets, touch pads, touch screens, still or video cameras, motion sensors, and/or microphones) and forwards the input to CPU 502 via memory bridge 505.

A display processor 512 is coupled to the memory bridge 505 via a bus or other communication path (e.g., a PCI Express, Accelerated Graphics Port, or HyperTransport link); in one embodiment display processor 512 is a graphics subsystem that includes at least one graphics processing unit (GPU) and graphics memory. Graphics memory includes a display memory (e.g., a frame buffer) used for storing pixel data for each pixel of an output image. Graphics memory can be integrated in the same device as the GPU, connected as a separate device with the GPU, and/or implemented within system memory 704.

Display processor 512 periodically delivers pixels of the dashboard to a display device 510 (e.g., a screen or conventional CRT, plasma, OLED, SED or LCD based monitor or television). Additionally, display processor 512 may output pixels to film recorders adapted to reproduce computer generated images on photographic film. Display processor 512 can provide display device 510 with an analog or digital signal.

Persistent storage 520 is also connected to I/O bridge 507 and may be configured to store content and applications and data, such as a database library 515, for use by CPU 502 and display processor 512. Persistent storage 520 provides non-volatile storage for applications and data and may include fixed or removable hard disk drives, flash memory devices, and CD-ROM, DVD-ROM, Blu-ray, HD-DVD, or other magnetic, optical, or solid state storage devices.

Illustratively, persistent storage 520 includes manufacturing data 590, which may comprise information acquired by the statistical analysis engine 122. Manufacturing data 590 may, for example, comprise information received from MES 432, collected by the manufacturing tools 140a-190c, related to various sensors taking measurements from substrates and tools over time during the manufacturing processes.

A switch 516 provides connections between the I/O bridge 507 and other components such as a network adapter 518 and various add-in cards 520 and 521. Network adapter 518 allows the system 500 to communicate with other systems via an electronic communications network, and may include wired or wireless communication over local area networks 540 and wide area networks such as the Internet.

Other components (not shown), including USB or other port connections, film recording devices, or other suitable computing device, may also be connected to I/O bridge 507. For example, process equipment 570 may operate from instructions and/or data provided by CPU 502, system memory 504, or persistent storage 520. Communication paths interconnecting the various components in FIG. 5 may be implemented using any suitable protocols, such as PCI (Peripheral Component Interconnect), PCI Express (PCI-E), AGP (Accelerated Graphics Port), HyperTransport, or any other bus or point-to-point communication protocol(s), and connections between different devices may use different protocols, as is known in the art.

The process equipment 570 may be one or more semiconductor chambers such as a plasma enhanced chemical vapor deposition (PECVD) or other plasma processing tool, such as the processing tools contained in the manufacturing tools 140a-190c. For example, process equipment 570 may be an etch chamber, a chemical vapor deposition chamber, a physical vapor deposition chamber, an implant chamber, a plasma treatment chamber, or other plasma processing chamber, either alone or in combination with one or more other chambers, such as manufacturing system 100.

In one embodiment, display processor 512 incorporates circuitry optimized for performing mathematical operations, including, for example, math co-processor, and may additionally constitute a graphics processing unit (GPU). In another embodiment, display processor 512 incorporates circuitry optimized for general purpose processing. In yet another embodiment, display processor 512 may be integrated with one or more other system elements, such as the memory bridge 505, CPU 502, and I/O bridge 507 to form a system on chip (SoC). In still further embodiments, display processor 512 is omitted and software executed by CPU 502 performs the functions of display processor 512.

Pixel data can be provided to display processor 512 directly from CPU 502. In some embodiments, instructions and/or data representing an excursion verification analysis is provided to set of server computers, each similar to the system 700, via network adapter 518 or system disk 514. The servers may perform operations on subsets of the data using the provided instructions for analysis. The results from these operations may be stored on computer-readable media in a digital format and optionally returned to the system 500 for further analysis or display. Similarly, data may be output to other systems for display, stored in a database library 515 on the system disk 514, or stored on computer-readable media in a digital format.

Alternatively, CPU 502 provides display processor 512 with data and/or instructions defining the desired output images, from which display processor 512 generates the pixel data of one or more output images, including characterizing and/or adjusting the offset between stereo image pairs. The data and/or instructions defining the desired output images can be stored in system memory 504 or graphics memory within display processor 512. CPU 502 and/or display processor 512 can employ any mathematical, function or technique known in the art to create one or more results from the provided data and instructions, including running models and comparing data from sensors to track the service life of chamber components.

It will be appreciated that the system shown herein is illustrative and that variations and modifications are possible. The connection topology, including the number and arrangement of bridges, may be modified as desired. For instance, in some embodiments, system memory 504 is connected to CPU 502 directly rather than through a bridge, and other devices communicate with system memory 504 via memory bridge 505 and CPU 502. In other alternative topologies display processor 512 is connected to I/O bridge 507 or directly to CPU 502, rather than to memory bridge 505. In still other embodiments, I/O bridge 507 and memory bridge 505 might be integrated into a single chip. The particular components shown herein are optional; for instance, any number of add-in cards or peripheral devices might be supported. In some embodiments, the process equipment 570 may be connected directly to the I/O bridge 507. In some embodiments, the switch 516 is eliminated, and the network adapter 518 and the add-in cards 520, 521 connect directly to the I/O bridge 507.

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Embodiments of the invention may be provided to end users through a cloud computing infrastructure. Cloud computing generally refers to the provision of scalable computing resources as a service over a network. More formally, cloud computing may be defined as a computing capability that provides an abstraction between the computing resource and its underlying technical architecture (e.g., servers, storage, networks), enabling convenient, on-demand network access to a shared pool of configurable computing resources that can be rapidly provisioned and released with minimal management effort or service provider interaction. Thus, cloud computing allows a user to access virtual computing resources (e.g., storage, data, applications, and even complete virtualized computing systems) in “the cloud,” without regard for the underlying physical systems (or locations of those systems) used to provide the computing resources.

Typically, cloud computing resources are provided to a user on a pay-per-use basis, where users are charged only for the computing resources actually used (e.g. an amount of storage space consumed by a user or a number of virtualized systems instantiated by the user). A user can access any of the resources that reside in the cloud at any time, and from anywhere across the Internet. In context of the present invention, a user may access applications (e.g., the statistical analysis engine 122) or related data available in the cloud. Doing so allows a user to access this information from any computing system attached to a network connected to the cloud (e.g., the Internet).

While the foregoing is directed to embodiments of the present invention, other and further embodiments of the invention may be devised without departing from the basic scope thereof, and the scope thereof is determined by the claims that follow.

What is claimed is:

1. A method for detecting mismatches among a plurality of manufacturing tools of the same type and operating on a first semiconductor wafer, comprising:
receiving metrological data and time series data applicable to the first semiconductor wafer from each of the plurality of manufacturing tools;
applying a plurality of statistical tests to the metrological data and a data mining technique to the time series data;
assigning a score to each result from applying the plurality of statistical test and the data mining technique to the plurality of manufacturing tools, the scores indicating a degree of mismatch among the plurality of manufacturing tools; and
responsive to the sum of scores exceeding a predetermined threshold,
declaring a mismatch condition for each tool among the plurality of manufacturing tools.

2. The method of claim 1, wherein the plurality of the statistical tests determines whether the metrological data exceeds wafer specification limits.

3. The method of claim 1, wherein the plurality of the statistical tests compares variances among chamber measurements in the metrological data.

4. The method of claim 1, wherein the plurality of the statistical tests are one or more tests for types of means in the metrological data.

5. The method of claim 1, wherein the plurality of the statistical tests are one or more t-tests for comparing chamber means.

6. The method of claim 1, wherein the plurality of the statistical tests are one or more comparisons of means for a full set of chambers comprising the set of manufacturing tools.

7. The method of claim 1, further comprising confirming the mismatch condition by employing one or more of the statistical tests to compare metrological data from one or more populations of semiconductor wafers to the metrological data from the one or more potential mismatching tools.

8. The method of claim 7, wherein the comparison of metrological data from a population of semiconductor wafers to the data from the one or more potential mismatching tools determines mismatches among multiple technologies, family codes, or measurement equipment.

9. The method of claim 7, wherein the comparison of metrological data from a population of semiconductor wafers to the metrological data from the one or more potential mismatching tools compares analyses of paired tool sets.

10. The method of claim 1, wherein the data mining technique is a dynamic time warping technique.

11. The method of claim 10, wherein the dynamic time warping technique outputs results comprising a statistical score that is based on a time series shape of the time series data.

12. The method of claim 1, wherein applying the plurality of statistical tests determines one or more mismatches that are operationally significant based on wafer specifications.

13. The method of claim 1, wherein declaring a mismatch condition generates an inhibit operation signal to disable each mismatched tool among the plurality of manufacturing tools.

14. The method of claim 1, further comprising, in response to declaring a mismatch condition, providing instructions to take a corrective action among the mismatched manufacturing tools.

15. The method of claim 1, further comprising generating a report including the tool scores.

16. The method of claim 1, further comprising generating a report including tool scores for the multiple parameters indexed by the semiconductor wafers.

17. A system, comprising:
a memory; and
a processor configured to perform a method for detecting mismatches among a plurality of manufacturing tools of the same type and operating on a first semiconductor wafer, the method comprising:
receiving metrological data and time series data applicable to the first semiconductor wafer from each of the plurality of manufacturing tools;
applying a plurality of statistical tests to the metrological data and a data mining technique to the time series data;
assigning a score to each result from applying the plurality of statistical test and the data mining technique to the plurality of manufacturing tools, the scores indicating a degree of mismatch among the plurality of manufacturing tools; and
responsive to the sum of scores exceeding a predetermined threshold,
declaring a mismatch condition for each tool among the plurality of manufacturing tools.

18. The system of claim 17, further comprising confirming the mismatch condition by employing one or more of the statistical tests to compare metrological data from one or more populations of semiconductor wafers to the metrological data from the one or more potential mismatching tools.

19. A computer program product for detecting mismatches among a plurality of manufacturing tools of the same type and operating on a first semiconductor wafer, the computer program product comprising:
a computer-readable storage medium having computer-readable program code embodied therewith, the computer-readable program code executable by one or more computer processors to:
receive metrological data and time series data applicable to the first semiconductor wafer from each of the plurality of manufacturing tools;
apply a plurality of statistical tests to the metrological data and a data mining technique to the time series data;
assign a score to each result from applying the plurality of statistical test and the data mining technique to the plurality of manufacturing tools, the scores indicating a degree of mismatch among the plurality of manufacturing tools
responsive to the sum of scores exceeding a predetermined threshold,
declaring a mismatch condition for each tool among the plurality of manufacturing tools.

20. The computer program product of claim 19, further comprising confirming the mismatch condition by employing one or more of the statistical tests to compare metrological data from one or more populations of semiconductor wafers to the metrological data from the one or more potential mismatching tools.
